(19) United States
(12) Patent Application Publication
(10) Pub. No.: US 2026/0371653 A1
(43) Pub. Date: Nov. 19, 2026

(54) SEMICONDUCTOR DEVICE

(71) Applicant: Taiwan Semiconductor Manufacturing Company, Ltd., Hsinchu (TW)

(72) Inventors: Wei-Sheng Yun, Taipei City (TW); Shao-Ming Yu, Hsinchu County (TW); Yun-Yan Chung, Hsinchu (TW); Tung-Ying Lee, Hsinchu City (TW); Chao-Ching Cheng, Hsinchu City (TW)

(73) Assignee: Taiwan Semiconductor Manufacturing Company, Ltd., Hsinchu (TW)

(21) Appl. No.: 19/752,700

(22) Filed: Jul. 24, 2026

Related U.S. Application Data
(63) Continuation of application No. 18/433,412, filed on Feb. 6, 2024.

(51) Int. Cl. H10D 30/67; H10D 30/01; H10D 30/47; H10D 30/62; H10D 62/10; H10D 64/01; H10D 84/01; H10D 84/03; H10D 84/85

(52) U.S. Cl. CPC H10D 30/6735; H10D 30/024; H10D 30/47; H10D 30/6211; H10D 30/6219; H10D 30/6729; H10D 62/121; H10D 64/017; H10D 64/021; H10D 84/017; H10D 84/0184; H10D 84/0193; H10D 84/038; H10D 84/853

(57) ABSTRACT

In a method of manufacturing a semiconductor device, a fin structure including a lower fin structure and an upper fin structure disposed over the lower fin structure is formed, wherein the upper fin structure includes dielectric layers and multi-film layers alternately stacked, each of the multi-film layers includes a channel layer, a first protection layer and a second protection layer, and the channel layer is between the first protection layer and the second protection layer. A sacrificial gate structure is formed over the upper fin structure. A source/drain epitaxial layer is formed over a source/drain region of the fin structure after forming the sacrificial gate structure over the upper fin structure. The sacrificial gate structure is removed after forming the source/drain epitaxial layer. The dielectric layers are removed after removing the sacrificial gate structure. A gate structure is formed around the multi-film layers.

### CROSS-REFERENCE TO RELATED APPLICATION

This application is a continuation application of and claims the priority benefit of a prior application Ser. No. 18/433,412, filed on Feb. 6, 2024 and now pending. The entirety of the above-mentioned patent applications is hereby incorporated by reference herein and made a part of this specification.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET), including a fin FET (Fin FET) and a gate-all-around (GAA) FET. In a GAA FET, all side surfaces of the channel region are surrounded by the gate electrode, which allows for fuller depletion in the channel region and results in less short-channel effects due to steeper sub-threshold current swing (SS) and smaller drain induced barrier lowering (DIBL). As transistor dimensions are continually scaled down to sub 10-15 nm technology nodes, further improvements of the GAA FET are required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 shows a view of one of the various stages of a sequential manufacturing process for a GAA FET device according to an embodiment of the present disclosure.

FIG. 2 shows a view of one of the various stages of a sequential manufacturing process for a GAA FET device according to an embodiment of the present disclosure.

FIGS. 3A and 3B show various views of one of the various stages of a sequential manufacturing process for a GAA FET device according to an embodiment of the present disclosure.

FIG. 4 shows a view of one of the various stages of a sequential manufacturing process for a GAA FET device according to an embodiment of the present disclosure.

FIGS. 5A, 5B, 5C and 5D show various views of one of the various stages of a sequential manufacturing process for a GAA FET device according to an embodiment of the present disclosure.

FIGS. 6A, 6B, 6C and 6D show various views of one of the various stages of a sequential manufacturing process for a GAA FET device according to an embodiment of the present disclosure.

FIGS. 7A, 7B, 7C, 7D and 7E show various views of one of the various stages of a sequential manufacturing process for a GAA FET device according to an embodiment of the present disclosure.

FIGS. 8A, 8B, 8C, 8D and 8E show various views of one of the various stages of a sequential manufacturing process for a GAA FET device according to an embodiment of the present disclosure.

FIGS. 9A, 9B, 9C, 9D, 9E and 9F show various views of one of the various stages of a sequential manufacturing process for a GAA FET device according to an embodiment of the present disclosure.

FIGS. 10A, 10B, 10C and 10D show various views of one of the various stages of a sequential manufacturing process for a GAA FET device according to an embodiment of the present disclosure.

FIGS. 11A-11E show various views of one of the various stages of a sequential manufacturing process for a GAA FET device according to an embodiment of the present disclosure.

FIGS. 12A and 12B show various views of one of the various stages of a sequential manufacturing process for a GAA FET device according to an alternative embodiment of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or process in addition to the orientation depicted in the figures. The apparatus may be otherwise oriented (rotated 90 degrees or at other orientations) and the spatially relative descriptors used herein may likewise be interpreted accordingly.

In the following embodiments, material, configurations, dimensions, operations and/or processes of one embodiment may be employed in another embodiment, unless otherwise described, and detailed explanation thereof may be omitted.

Gate-all-around (GAA) FETs with nano-sized semiconductor wires or nano-sized semiconductor channels, such as nanowires or nanosheets, are promising devices for the further technology nodes in semiconductor integrated circuits, to realize lower operational power, higher device performance, higher device density and lower process cost, etc. In a GAA FET manufacturing flow, how or increase the yield rate of processes for fabricating the nano-sized semiconductor wires is a key challenge in terms of above criteria.

In embodiments of the present disclosure, a semiconductor device (e.g., a GAA FET device) and a method of manufacturing the same to solve the issue of fabrication yield rate are presented. The discussed following manufacturing method for a GAA FET device is compatible with currently used manufacturing processes.

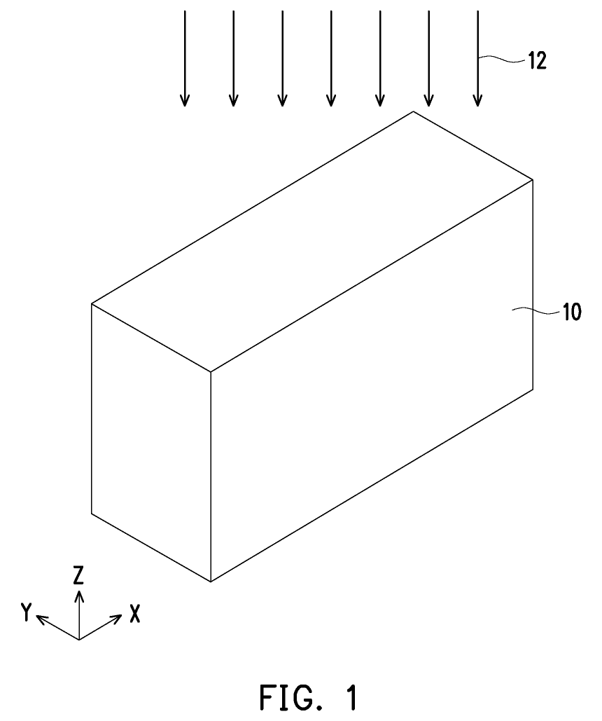

FIGS. 1-11E show a sequential process for manufacturing a GAA FET device according to an embodiment of the present disclosure. It is understood that additional process steps can be provided before, during, and after the process steps shown by FIGS. 1-11E, and some of the process steps described below can be replaced or eliminated, for additional embodiments of the method. The order of the process steps may be interchangeable.

Referring to FIG. 1, a substrate 10 is provided. In some embodiments, the substrate 10 is a semiconductor substrate, such as, but not limited to a silicon substrate. As shown in FIG. 1, impurity ions (dopants) 12 are implanted into the substrate 10 to form a well region. The ion implantation is performed to prevent a punch-through effect. In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In one embodiment, the substrate 10 is made of crystalline Si.

The substrate 10 may include in its surface region, one or more buffer layers (not shown). The buffer layers may serve to gradually change the lattice constant from that of the substrate 10 to that of the subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In some embodiments, the substrate 10 includes silicon germanium (SiGe) buffer layers epitaxially grown on the silicon substrate 10. The Ge concentration of the SiGe buffer layers may increase from 30 atomic% germanium for the bottom-most buffer layer to 70 atomic% germanium for the top-most buffer layer. The substrate 10 may include various regions that have been suitably doped with impurities (e.g., p-type or n-type conductivity). The dopants 12 are, for example boron (BF₂) for an n-type Fin FET and phosphorus for a p-type Fin FET.

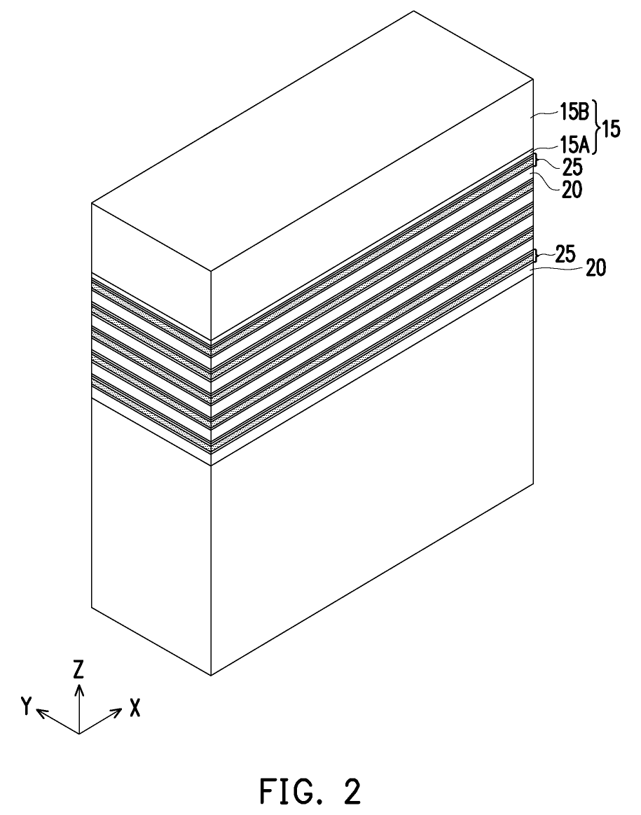

Referring to FIG. 2, stacked layers are formed over the substrate 10. The stacked layers include dielectric layers 20 and multi-film layers 25 stacked alternately. The dielectric layers 20 function as sacrificial layers to maintain the positions of the multi-film layers 25 during the subsequently performed processes. Further, a mask layer 15 is formed over the stacked layers including the dielectric layers 20 and the multi-film layers 25 stacked alternately. The multi-film layers 25 may each includes a first protection layer P1 disposed on a surface of the underlying dielectric layer 20, a second protection layer P2 disposed over the first protection layer P1, and a channel layer 25b disposed between the first protection layer P1 and the second protection layer P2, wherein the first protection layer P1 includes a first etch resistive layer 25a, the second protection layer P2 includes a second etch resistive layer 25d disposed on the first etch resistive layer 25a as well as an adhesion layer 25c disposed between the channel layer 25b and the second etch resistive layer 25d. As shown in FIG. 2, the first protection layer P1 includes a single-layered structure, and the second protection layer P2 includes a multi-layered structure.

The material of the first etch resistive layer 25a may be or include AlOₓ or other suitable dielectric materials. The material of the adhesion layer 25c may be or include AlOₓ or other suitable dielectric materials. The adhesion layer 25c may be a metal-rich high-k dielectric layer. The metal ratio in the adhesion layer 25c may be greater than the metal ratio in the etch resistive layer 25a. The material of the second etch resistive layer 25d may be or include AlOₓ or other suitable dielectric materials. For example, the first etch resistive layer 25a and the second etch resistive layer 25d are substantially identical in material and thickness. Furthermore, the film density of the first etch resistive layer 25a and the second etch resistive layer 25d may be greater than that of the adhesion layer 25c. In an embodiment where the channel layer 25b includes 2D material, the channel layer 25 can be easily laminated onto the first etch resistive layer 25a, and the adhesion layer 25c may enhance the adhesion between the channel layer 25b and the second etch resistive layer 25d such that the top surfaces and the bottom surfaces of the channel layer 25b can be well protected by the adhesion layer 25c and the second etch resistive layer 25d during the subsequently performed processes. As illustrated in FIG. 2, no adhesion layer is formed between the first etch resistive layer 25a and the channel layer 25b. In some other embodiments, not illustrated in Figures, an additional adhesion layer is formed between the first etch resistive layer and the channel layer if necessary.

In some other embodiments, the dielectric layers 20 are made of dielectric material, such as silicon oxide, silicon nitride, silicon oxynitride (SiON) or other suitable dielectric materials. In some embodiments, the channel layers 25b of the multi-film layers 25 are made of 2D materials, such as transition-metal dichalcogenide monolayers (e.g., MoS₂), graphene or the like. In some other embodiments,the channel layers 25b of the multi-film layers 25 are made of materials having different lattice constants, and may include one or more layers of Si, Ge, SiGe, GeSn, SiGeSn, GaAs, InSb, GaP, GaSb, InAlAs, InGaAs, GaSbP, GaAsSb or InP. In some alternative embodiments, the channel layers 25b of the multi-film layers 25 are made of Si, a Si compound, SiGe, Ge or a Ge compound. For example, the channel layers 25b of the multi-film layers 25 are made of Si or Si_{1-y}Ge_{y}, where y is equal to or less than about 0.2 and x > y.

As shown in FIG. 2, five layers of the dielectric layer 20 and five layers of the multi-film layer 25 are disposed. However, the number of the dielectric layers 20 and the number of the multi-film layers 25 are not limited to five, and may be as small as 1 (each of the dielectric layers and the semiconductor layers) and in some embodiments, two to twenty layers of each of the dielectric layers 20 and multi-film layers 25 are formed. Through properly adjusting the numbers of the stacked layers, a driving current of the GAA FET device can be adjusted.

In some other embodiments, the dielectric layers 20 and the multi-film layers 25 are deposited or epitaxially grown over the substrate 10. The thickness of the dielectric layers 20 may be substantially equal to or smaller than that of the multi-film layers 25, and is in a range from about 2 nm to about 10 nm in some embodiments, and is in a range from about 3 nm to about 5 nm in some other embodiments. The thickness of the multi-film layers 25 is in a range from about 5 nm to about 20 nm in some embodiments, and is in a range from about 7.5 nm to about 12.5 nm in some other embodiments. The thickness of each of the dielectric layers 20 and the multi-film layers 25 may be the same, or may vary.

In some embodiments, the bottommost dielectric layer (the closest layer to the substrate 10) is thicker than the remaining dielectric layers. The thickness of the bottommost dielectric layer is in a range from about 10 nm to about 50 nm in some embodiments, or is in a range from 20 nm to 40 nm in some other embodiments.

In some embodiments, the mask layer 15 includes a first mask layer 15A and a second mask layer 15B. The first mask layer 15A may be a pad oxide layer made of a silicon oxide, which can be formed by a thermal oxidation process. The second mask layer 15B may be made of a silicon nitride (SiN), which is formed by chemical vapor deposition (CVD), including low pressure CVD (LPCVD) and plasma enhanced CVD (PECVD), physical vapor deposition (PVD), atomic layer deposition (ALD), or other suitable process. The mask layer 15 is patterned into a mask pattern by using a patterning process including photo-lithography followed by etching.

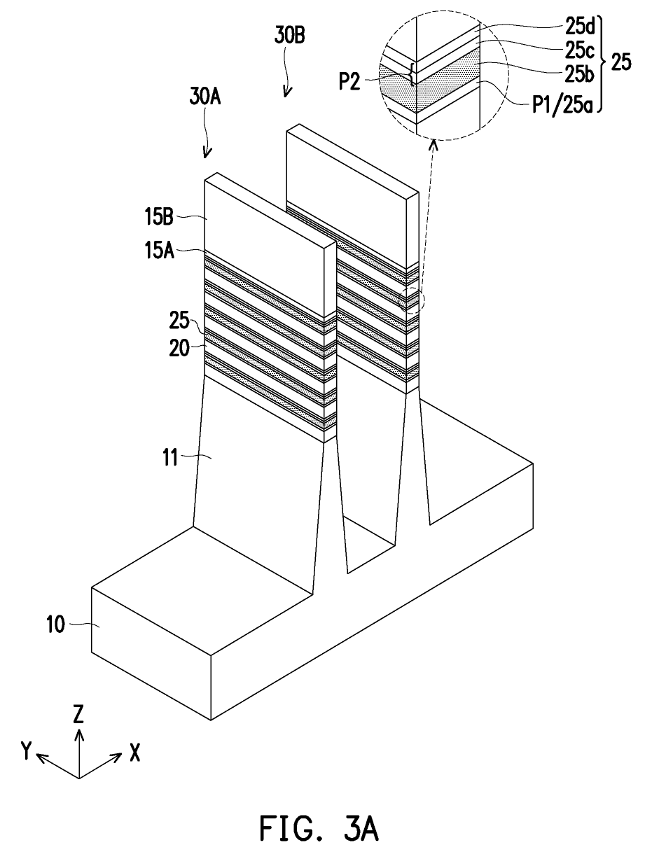

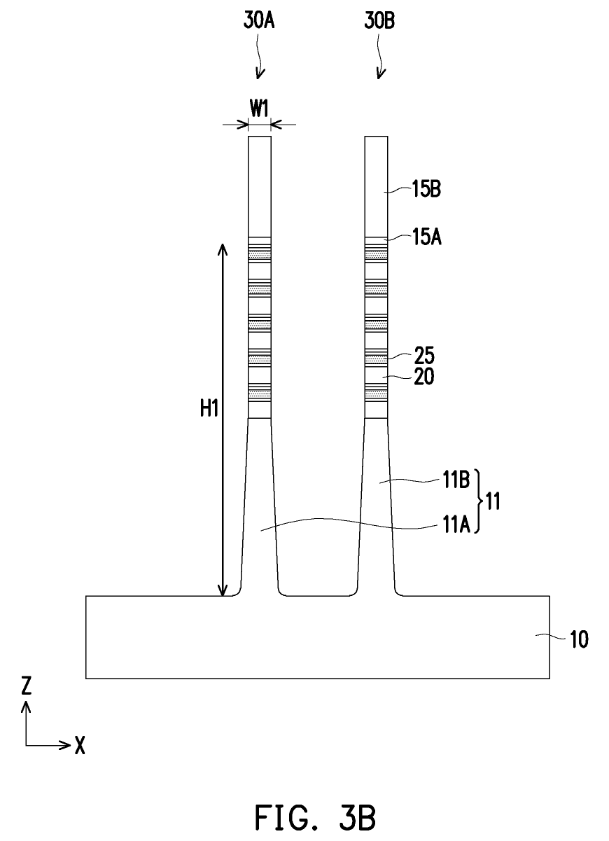

Referring to FIGS. 3A and 3B, the stacked layers of the the dielectric layers 20 and the multi-film layers 25 are patterned by using the patterned mask layer 15, thereby the stacked layers are formed into multiple fin structures 30. As illustrated in FIG. 3A, the fin structures 30 extend in the Y direction and arranged along the X direction. The fin structures 30 may be patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structures.

In FIGS. 3A and 3B, two upper fin structures 30A and 30B are illustrated and are arranged in the X direction. But the number of the fin structures 30 is not limited to two, and may be as small as one and three or more. In some embodiments, one or more dummy fin structures (not illustrated in Figures) are formed on both sides of the fin structures 30 to improve pattern fidelity in the patterning process. In other words, the dummy fin structures may minimize loading effect. As shown in FIGS. 3A and 3B, the fin structures 30 include upper portions constituted by the stacked layers 20, 25, and the fin structures 30 further include well portions 11 disposed under the upper fin structures 30A and 30B. The upper portions are referred as to the upper fin structures 30A and 30B of the fin structure 30, and the well portions 11 are referred as to the lower fin structures of the fin structure 30. In some embodiments, the upper fin structure 30A is for a p-channel GAA FET and the fin structure 30B is for an n-channel GAA FET. As shown in FIG. 3B, the upper fin structures 30A and 30B are disposed over lower fin structures 11A and 11B, respectively. In some other embodiments, the upper fin structures 30A and 30B are for the same type FET.

The width W1 of the upper portion of the fin structure 30 along the X direction is in a range from about 5 nm to about 30 nm in some embodiments, and is in a range from about 7.5 nm to about 15 nm in other embodiments. The height H1 along the Z direction of the fin structure 30 is in a range from about 50 nm to about 200 nm.

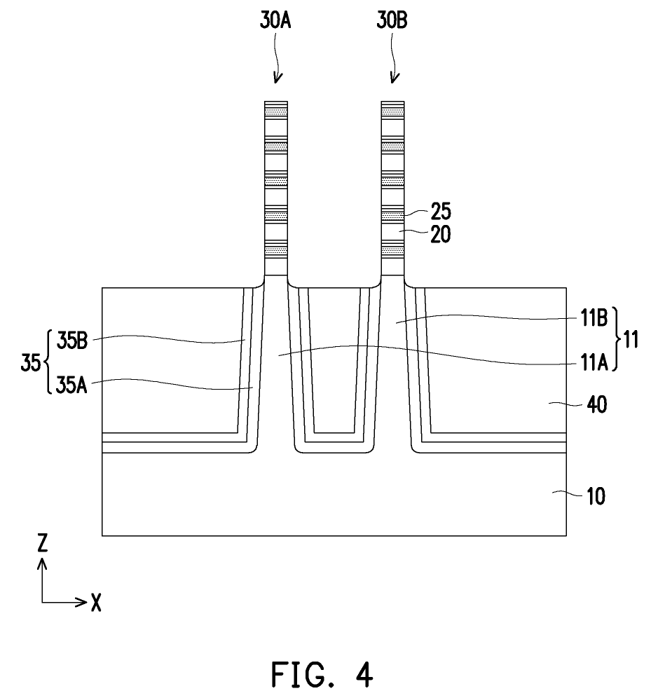

Referring to FIG. 4, one or more fin liner layers 35 and the isolation insulating layer 40 are formed over the substrate 10. For example, an insulating material layer including one or more layers of insulating material is formed over the substrate 10 so that the upper fin structures 30A and 30B are fully embedded in the insulating material layer. The insulating material for the insulating material layer may be or include silicon oxide, silicon nitride, silicon oxynitride (SiON), SiOCN, SiCN, fluorine-doped silicate glass (FSG), or a low-K dielectric material, formed by LPCVD (low pressure chemical vapor deposition), plasma-CVD or flowable CVD. An anneal process may be performed after the formation of the insulating material layer. Then, a planarization process, such as a chemical mechanical polishing (CMP) method and/or an etch-back method, is performed such that the upper surface of the uppermost multi-film layer 25 is exposed from the insulating material layer.

In some embodiments, one or more fin liner layers 35 are formed before forming the insulating material layer, as shown FIG. 4. The fin liner layer 35 are made of SiN or a silicon nitride-based material (e.g., SiON, SiCN or SiOCN). In some embodiments, the fin liner layers 35 include a first fin liner layer 35A formed over the substrate 10 and side faces of the bottom fin structures 11, and a second fin liner layer 35B formed on the first fin liner layer 35A. Each of the liner layers has a thickness between about 1 nm and about 20 nm in some embodiments. For example, the first fin liner layer 35A includes silicon oxide and has a thickness between about 0.5 nm and about 5 nm, and the second fin liner layer 35B includes silicon nitride and has a thickness between about 0.5 nm and about 5 nm. The fin liner layers 35 may be deposited through one or more processes such as physical vapor deposition (PVD), chemical vapor deposition (CVD), or atomic layer deposition (ALD), although any acceptable process may be utilized.

Then, as shown in FIG. 4, a recessing process (e.g., an etch process) of the insulating material layer is performed such that the insulating material layer is recessed to form an isolation insulating layer 40 so that the upper portions of the fin structures 30 are exposed. With this operation, the upper fin structures 30 are electrically separated from each other by the isolation insulating layer 40, which is also called a shallow trench isolation (STI). In the embodiment shown in FIG. 4, the insulating material layer is recessed until the tops of the lower fin structures 11 are exposed. The dielectric layers 20 function as sacrificial layers which are subsequently partially removed, and the multi-film layers 25 are subsequently formed as well as function as channel layers of a GAA FET. During the recessing process of the insulating material layer, the widths of the dielectric layers 20 may be reduced by the etchant used in the recessing process.

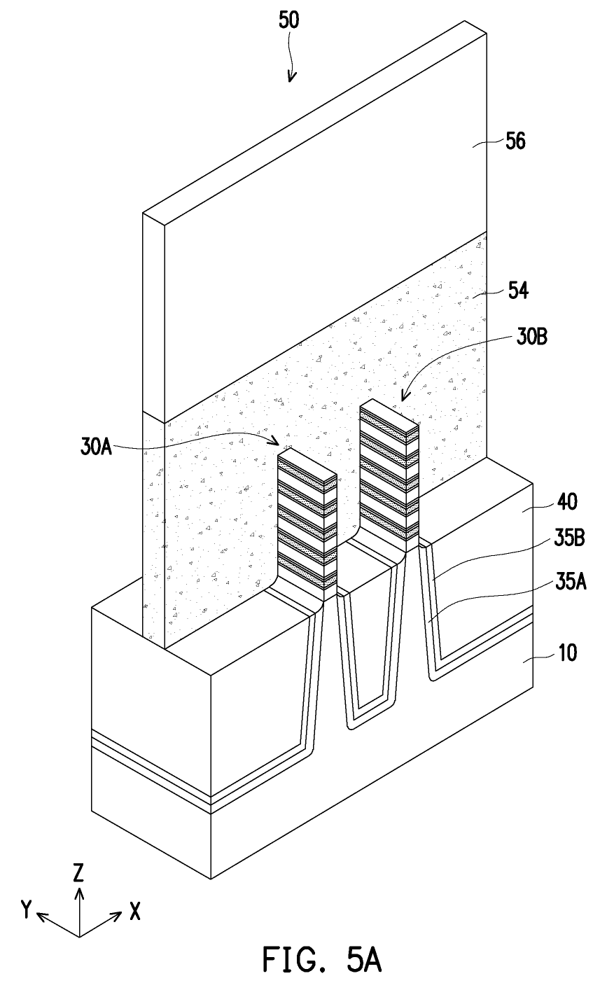

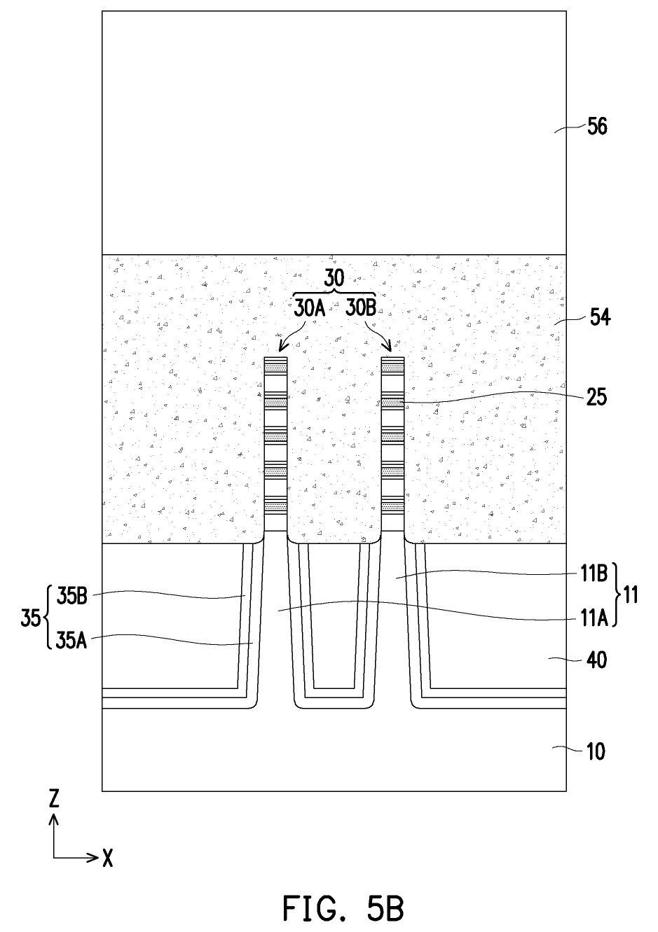

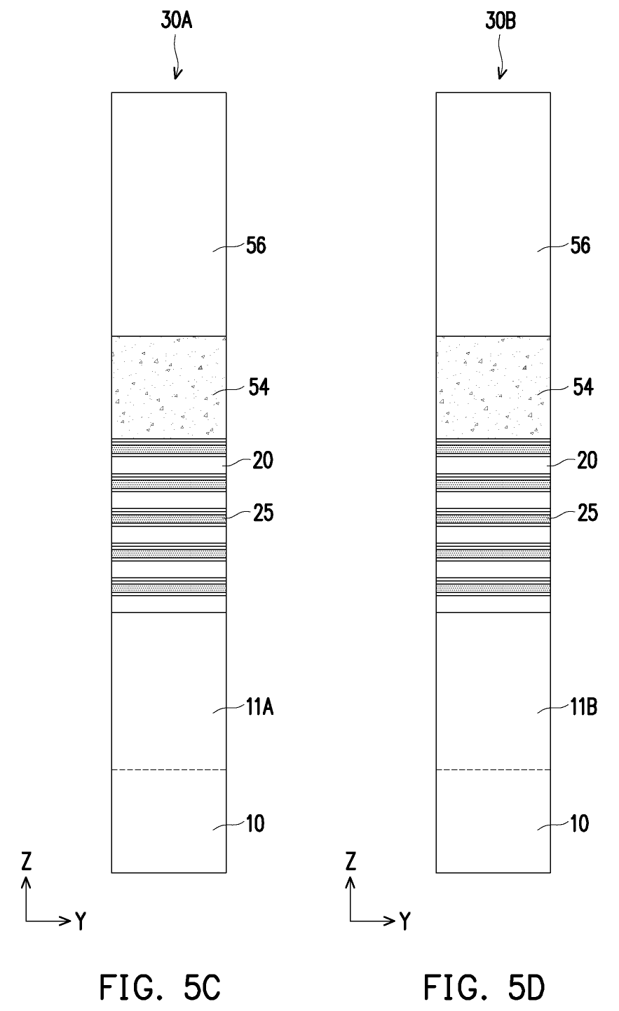

Referring to FIGS. 5A-5D, after the isolation insulating layer 40 is formed, a sacrificial gate structure 50 is formed over the upper fin structures 30A and 30B with the oxide layer 45. FIG. 5A shows a perspective view, FIG. 5B shows a cross sectional view along the X direction cutting a sacrificial gate structure, FIG. 5C shows a cross sectional view along the Y direction cutting the upper fin structure 30A, and FIG. 5D shows a cross sectional view along the Y direction cutting the upper fin structure 30B.

As illustrated in FIG. 5A, the sacrificial gate structure 50 includes a sacrificial gate electrode 54. In some embodiments, the sacrificial gate structure 50 includes no sacrificial gate dielectric layer. The sacrificial gate structure 50 is formed over portions of the upper fin structures 30A and 30B, and the portions of the upper fin structures 30A and 30B covered by the sacrificial gate structure 50 are to be channel regions. In other words, the sacrificial gate structure 50 defines the channel regions of the GAA FETs.

The sacrificial gate structure 50 is formed by first blanket depositing the sacrificial gate electrode layer over the upper fin structures 30A and 30B, such that the upper fin structures 30A and 30B are fully embedded in the sacrificial gate electrode layer. The sacrificial gate electrode layer includes silicon, such as polycrystalline silicon or amorphous silicon. The thickness of the sacrificial gate electrode layer is in a range from about 100 nm to about 200 nm in some embodiments. In some embodiments, the sacrificial gate electrode layer is subjected to a planarization process. The sacrificial gate electrode layer may be deposited using CVD, including LPCVD and PECVD, PVD, ALD, or other suitable process. Subsequently, a mask layer 56 is formed over the sacrificial gate electrode layer. The mask layer 56 includes one or more of a silicon nitride (SiN) layer and a silicon oxide layer.

A patterning process is then performed on the mask layer 56 such that the underlying sacrificial gate electrode layer is patterned into the sacrificial gate structure 50, as shown in FIGS. 5A-5D. The sacrificial gate structure 50 may include the sacrificial gate electrode layer 54 (e.g., poly silicon layer) and the mask layer 56.

By patterning the sacrificial gate structure 50, the upper fin structures 30A and 30B including the dielectric layers 20 and the multi-film layers 25 are partially exposed on opposite sides of the sacrificial gate structure 50, thereby defining source/drain (S/D) regions of the upper fin structures 30A and 30B, as shown in FIGS. 5A-5D. In this embodiment, a source and a drain are interchangeably used and the structures thereof are substantially the same. In FIGS. 5A-5D, only one sacrificial gate structure 50 is illustrated, but the number of the sacrificial gate structure 50 is not limited to one. Two or more sacrificial gate structures 50 are arranged in the Y direction in some embodiments. In some alternative embodiments, one or more dummy sacrificial gate structures are formed on both sides of the sacrificial gate structures to improve pattern fidelity. In other words, the dummy sacrificial gate structures may minimize loading effect.

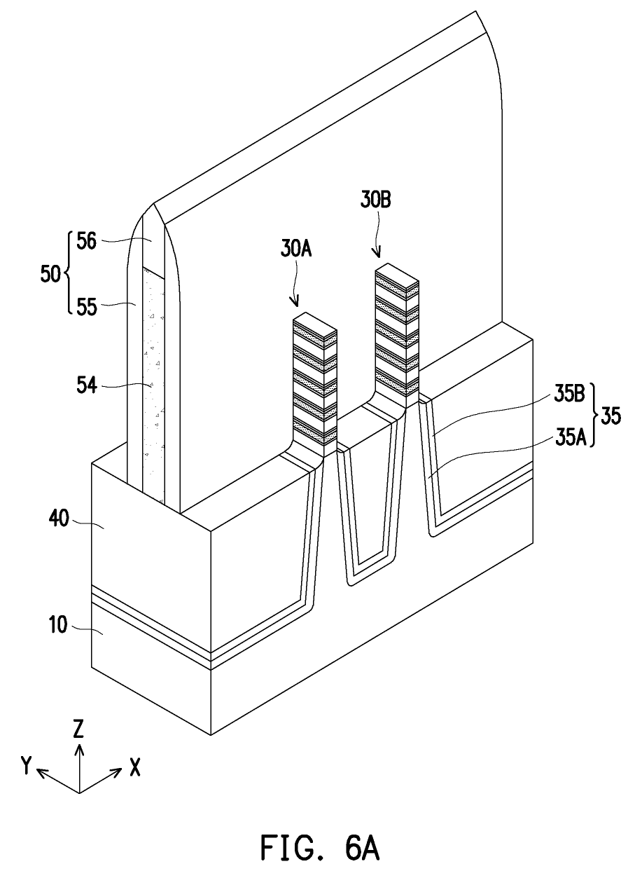

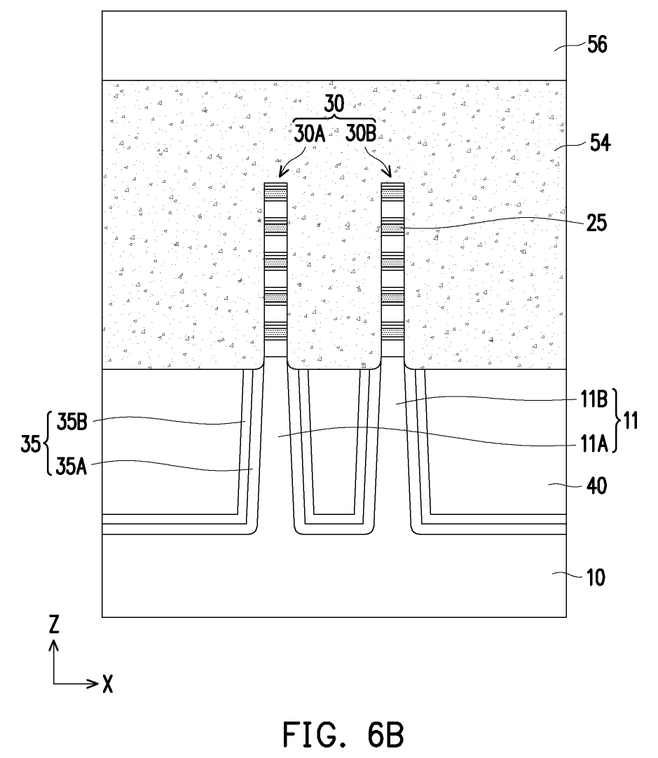

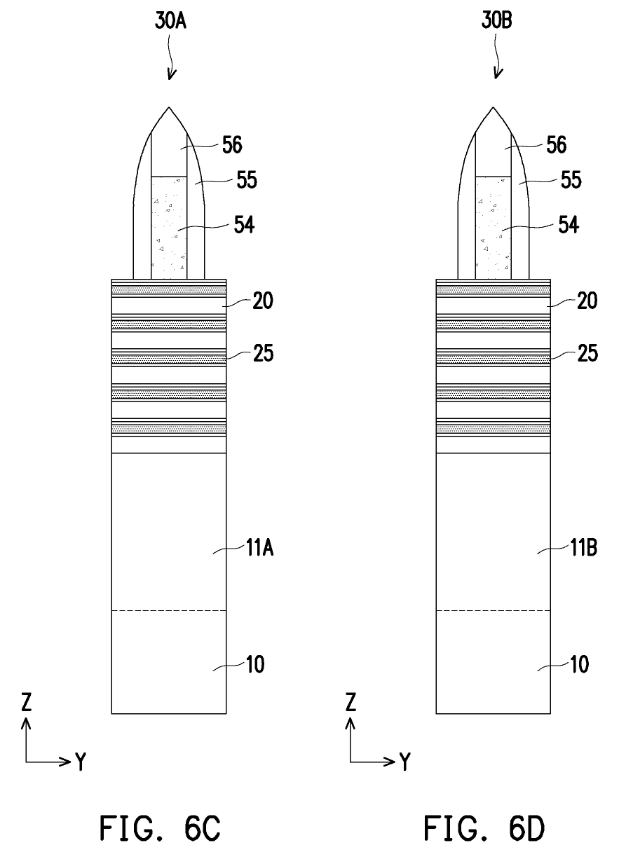

After the sacrificial gate structure 50 is formed, gate sidewall spacers 55 are formed on opposite sidewalls of the sacrificial gate structure 50, as shown in FIG. 6A through FIG. 6D. FIG. 6A shows a perspective view, FIG. 6B shows a cross sectional view along the X direction cutting the sacrificial gate structure 50, FIG. 6C shows a cross sectional view along the Y direction cutting the upper fin structure 30A, and FIG. 6D shows a cross sectional view along the Y direction cutting the upper fin structure 30B.

To form the gate sidewall spacer 55, a blanket layer of an insulating material is conformally formed by using CVD or other suitable methods. The blanket layer is deposited in a conformal manner so that it is formed to have substantially equal thicknesses on vertical surfaces, such as the sidewalls, horizontal surfaces, and the top of the sacrificial gate structure 50. In some embodiments, the blanket layer is deposited to a thickness in a range from about 2 nm to about 20 nm. In some embodiments, the insulating material of the blanket layer is a silicon nitride-based material, such as SiN, SiON, SiOCN or SiCN and combinations thereof. In some other embodiments, the insulating material is one of SiOC, SiCON and SiCN.

Further, as shown in FIGS. 6A-6D, the gate sidewall spacers 55 are formed on opposite sidewalls of the sacrificial gate structure 50 by an anisotropic etching. After the blanket layer is formed, anisotropic etching is performed on the blanket layer using, for example, reactive ion etching (RIE). During the anisotropic etching process, most of the insulating material is removed from horizontal surfaces, leaving the dielectric spacer layer on the vertical surfaces such as the sidewalls of the sacrificial gate structure 50 and the sidewalls of the exposed upper fin structures 30A and 30B. The mask layer 56 may be exposed from the gate sidewall spacers 55. In some embodiments, an isotropic etching process may be subsequently performed to remove the insulating material from the upper portions of the S/D regions of the exposed upper fin structures 30A and 30B.

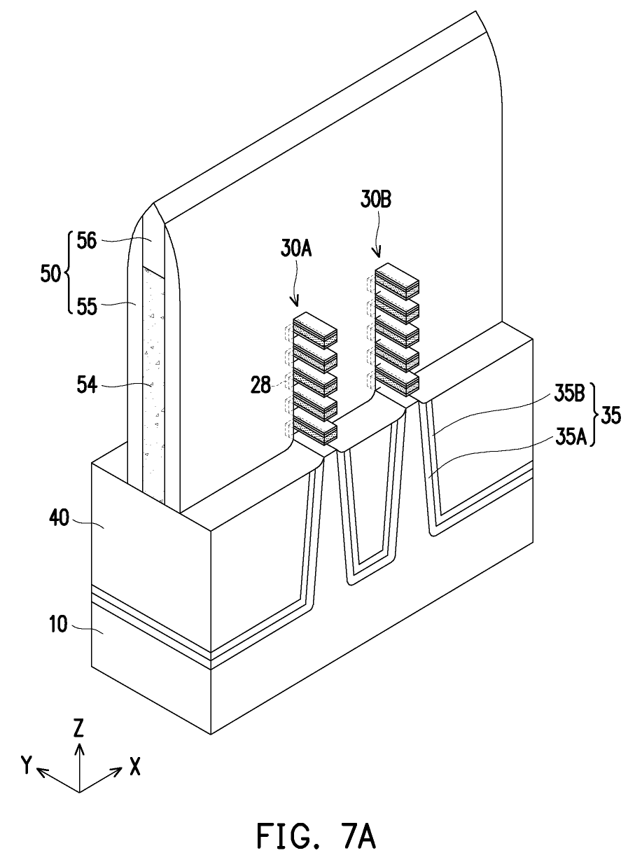

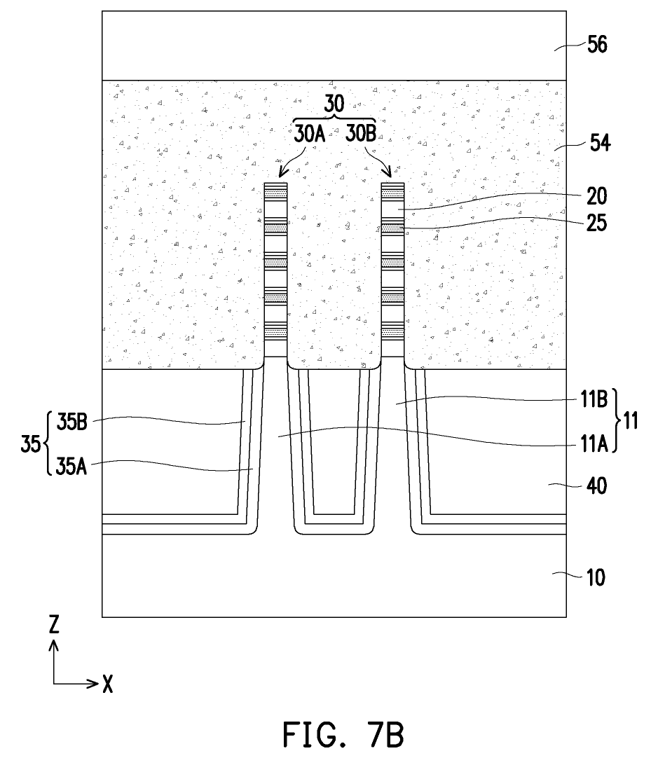

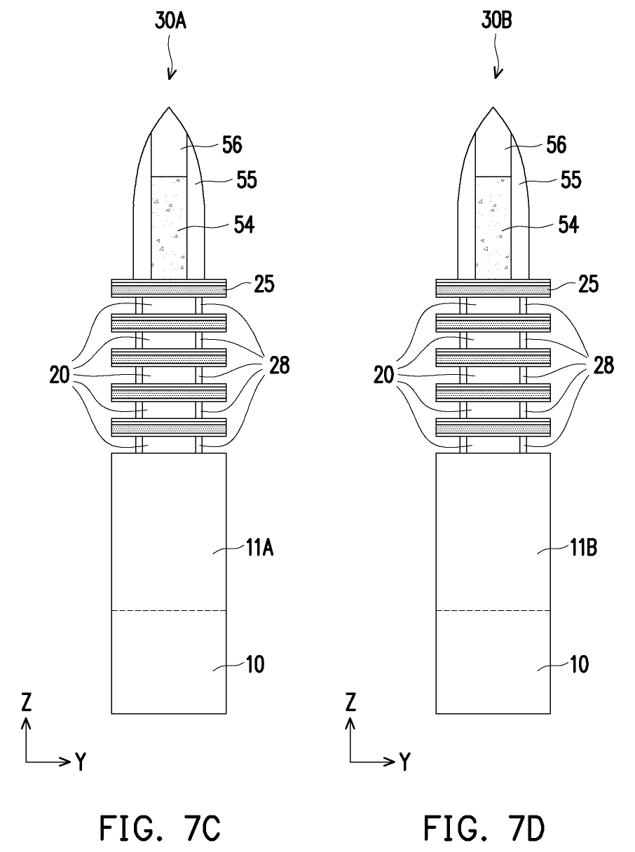

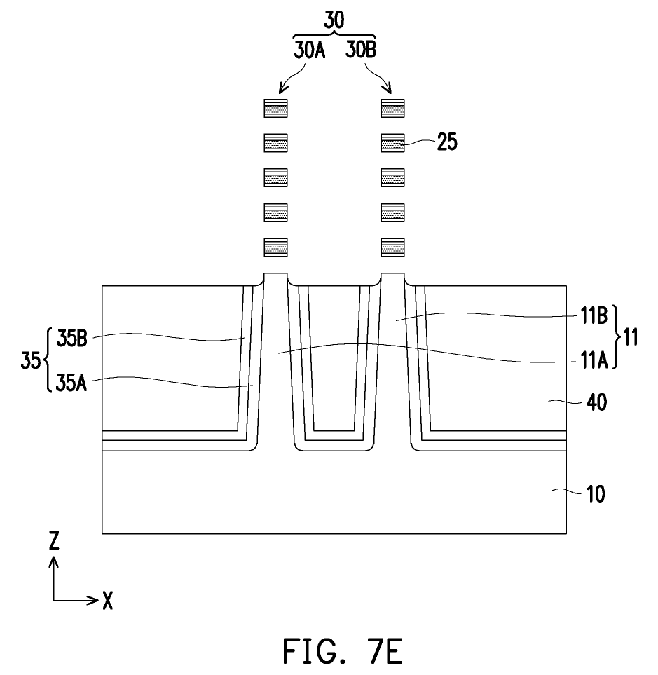

Referring to FIGS. 7A-7E, portions of the semiconductor layers 20 which are not covered by the sacrificial gate structure 50 are removed. FIG. 7A shows a perspective view, FIG. 7B shows a cross sectional view along the X direction cutting the sacrificial gate structure 50, FIG. 7C shows a cross sectional view along the Y direction cutting the upper fin structure 30A, FIG. 7D shows a cross sectional view along the Y direction cutting the upper fin structure 30B, and FIG. 7E shows a cross sectional view along the X direction cutting the source/drain regions.

As illustrated in FIGS. 7A-7E, the dielectric layers 20 are partially removed to reduce lengths of the dielectric layers 20 such that first ends of the dielectric layers 20 are located under the gate sidewall spacers 55. After the dielectric layers 20 are partially removed, multiple indentations arranged between neighboring multi-film layers 25 are formed in the gate sidewall spacers 55. In some embodiments, an anisotropic etching process may be performed to partially remove the dielectric layers 20 in the S/D regions of the upper fin structures 30A and 30B such that second ends of the multi-film layers 25 may protrude from the sidewalls of the sacrificial gate structure 50. For example, a dry etching process using a gaseous etchant is performed to remove portions of the dielectric layers 20, the dielectric layers 20 are etched by the gaseous etchant with a first etching rate, the multi-film layers 25 are etched by the gaseous etchant with a second etching rate, and the first etching rate is greater than the second etching rate. Since the significant difference between the first and second etching rate, the multi-film layers 25, especially the sidewalls of the channel layers 25b, are not damaged significantly. In some embodiment, the etching process of the dielectric layers 20 has a lower etching rate to the first etch resistive layers 25a of the multi-film layers 25, and the etching process of the dielectric layers 20 has a higher etching rate to the channel layers 25b of the multi-film layers 25. Furthermore, the etching process of the dielectric layers 20 has a lower etching rate to the second etch resistive layer 25d of the multi-film layers 25, and the etching process of the dielectric layers 20 has a higher etching rate to the adhesion layer 25c of the multi-film layers 25. In some embodiments, sidewalls of the channel layers 25b are laterally offset from sidewalls of the first protection layer P1 (e.g., the first etch resistive layers 25a) and sidewalls of the second protection layer P2 (e.g., the adhesion layer 25c and/or the second etch resistive layer 25d).

At this stage, the second ends of the multi-film layers 25 are laterally spaced apart from the sidewalls of the sacrificial gate structure 50 as well as the gate sidewall spacers 55. Furthermore, the second ends of the multi-film layers 25 are revealed and are not in contact with by the remaining dielectric layers 20 covered by the sacrificial gate structure 50.

After partially removing the dielectric layers 20 to reduce the lengths of the dielectric layers 20, inner spacers 28 are selectively formed on the first ends (e.g., end surfaces) of the dielectric layers 20, at this stage, the second ends of the multi-film layers 25 may laterally protrude from the inner spacers 28, and the dielectric layers 20 with reduced width are not revealed because the first ends (e.g., end surfaces) of the dielectric layers 20 are covered by the inner spacers 28. Furthermore, the inner spacers 28 are in contact with the multi-film layers 25. For example, each one of the inner spacers 28 extends vertically from a second etch resistive layer 25d of a lower multi-film layer 25 to a first etch resistive layer 25a of an upper multi-film layer 25. As illustrated in FIGS. 7C and 7D, the inner spacers 28 are located under the gate sidewall spacers 55, and the width of each one of the inner spacers 28 is less than the width of each one of the gate sidewall spacers 55. In other words, the inner spacers 28 are directly below the gate sidewall spacers 55. In some other embodiments, not shown in figures, the inner spacers 28 are located under the gate sidewall spacers 55, and the width of each one of the inner spacers 28 is greater than the width of each one of the gate sidewall spacers 55. In other words, the inner spacers 28 are not entirely covered by the gate sidewall spacers 55.

A conformal deposition of an insulating material followed by an etch-back method may be performed such that the inner spacers 28 can be selectively formed on the end surfaces of the dielectric layers 20. To form the inner spacers 28, a blanket layer of an insulating material may be conformally formed by using CVD or other suitable methods. In some embodiments, the insulating material of the blanket layer for fabricating the inner spacers 28 is a silicon nitride-based material, such as SiN, SiON, SiOCN or SiCN and combinations thereof. In some other embodiments, the insulating material of the blanket layer for fabricating the inner spacers 28 is one of SiOC, SiCON and SiCN. For example, the thickness of the inner spacers 28 is in a range from about 0.2 nm to about 2 nm in some embodiments.

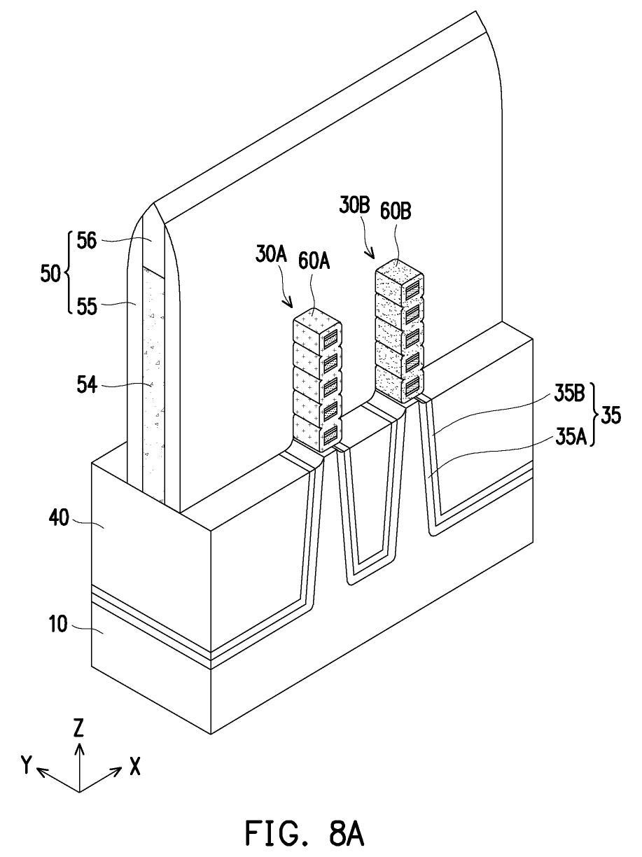

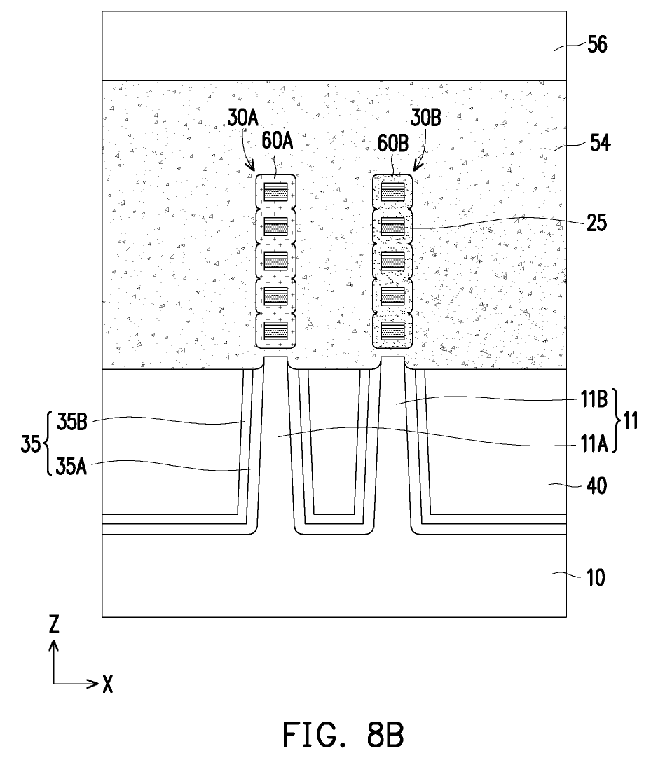

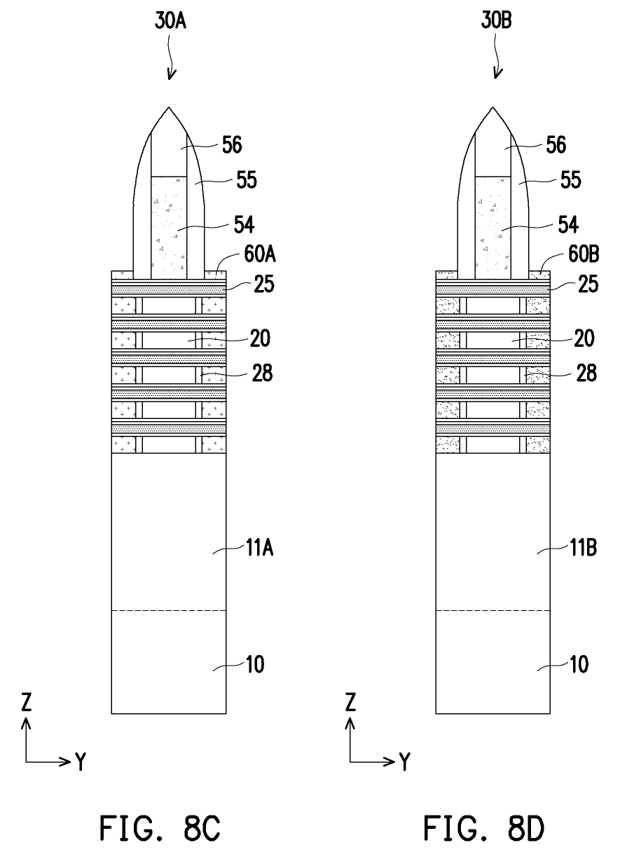

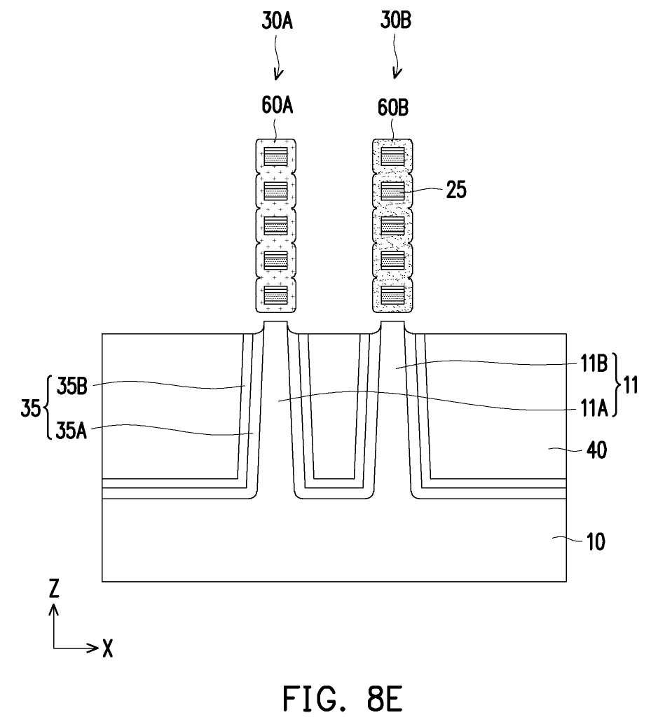

Referring to FIGS. 8A-8E, source/drain epitaxial layers 60A and 60B are formed on opposite sides of the sacrificial gate structure 50. Sidewalls of the channel layers 25b (shown in FIG. 3A) of the multi-film layers 25 are in contact with the first S/D epitaxial layer 60A and the second S/D epitaxial layer 60B such that the channel layers 25b (shown in FIG. 3A) of the multi-film layers 25 are electrically connected the first S/D epitaxial layer 60A and the second S/D epitaxial layer 60B. FIG. 8A shows a perspective view, FIG. 8B shows a cross sectional view along the X direction cutting the sacrificial gate structure 50, FIG. 8C shows a cross sectional view along the Y direction cutting the upper fin structure 30A, FIG. 8D shows a cross sectional view along the Y direction cutting the upper fin structure 30B, and FIG. 8E shows a cross sectional view along the X direction cutting the source/drain regions.

The first S/D epitaxial layer 60A is formed wrapping around the multi-film layers 25 in the S/D regions of the upper fin structure 30A. The first S/D epitaxial layer 60A includes one or more layers of Si, SiGe and SiGeP for a p-channel FET. The first S/D epitaxial layer 60A is formed by an epitaxial growth method using CVD, ALD or molecular beam epitaxy (MBE). In some embodiments, boron (B) is contained in the first S/D epitaxial layer 60A. The second S/D epitaxial layer 60B is formed wrapping around the multi-film layers 25 in the S/D region of the upper fin structure 30B. The second S/D epitaxial layer 60B includes one or more layers of Si, SiP, SiC and SiCP for an n-channel FET. The second S/D epitaxial layer 60B is formed by an epitaxial growth method using CVD, ALD or molecular beam epitaxy (MBE). In some embodiments, the first source/drain (S/D) epitaxial layer 60A for a p-channel FET and the second S/D epitaxial layer 60B for an n-channel FET are separately formed. The sequence of formation of the first S/D epitaxial layer 60A and the second S/D epitaxial layer 60B is not limited. In some embodiments, the formation of the first S/D epitaxial layer 60A may be prior to the formation of the second S/D epitaxial layer 60B, and the upper fin structure 30A may be covered and protected by a layer (e.g., a dielectric layer, a photoresist layer or other suitable layer) when forming the second S/D epitaxial layer 60B. In some other embodiments, the formation of the second S/D epitaxial layer 60B may be prior to the formation of the first S/D epitaxial layer 60A, and the upper fin structure 30B may be covered and protected by a layer (e.g., a dielectric layer, a photoresist layer or other suitable layer) when forming the first S/D epitaxial layer 60A.

As illustrated in FIGS. 8A-8E, after the inner spacers 28 are formed on the first ends of the dielectric layers 20, the second ends of the multi-film layers 25 laterally protrude from the inner spacers 28. Furthermore, after the source/drain epitaxial layers 60A and 60B are formed, the source/drain epitaxial layers 60A and 60B cover the inner spacers 28 as well as wrap the second ends of the multi-film layers 25.

As illustrated in FIGS. 8A-8E, the source/drain epitaxial layers 60A and 60B are spaced apart from the sacrificial gate electrode layer 54 by the inner spacers 28.

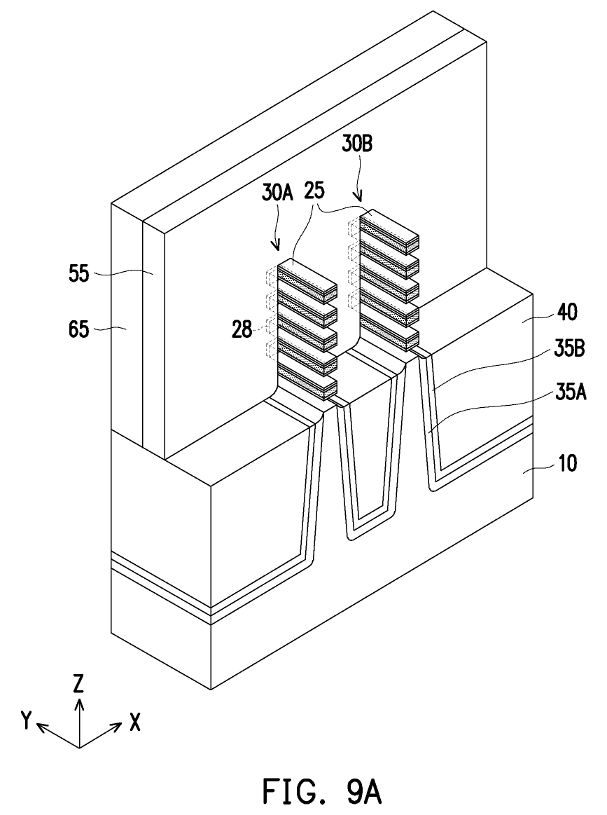

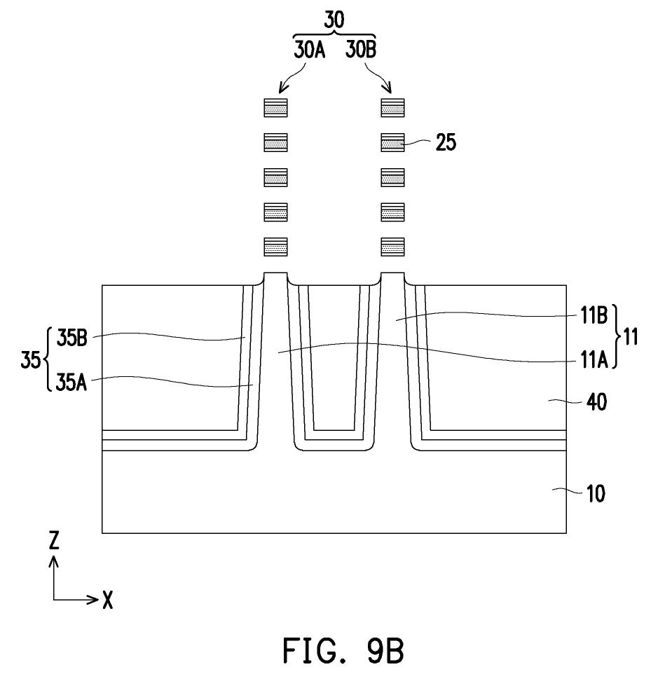

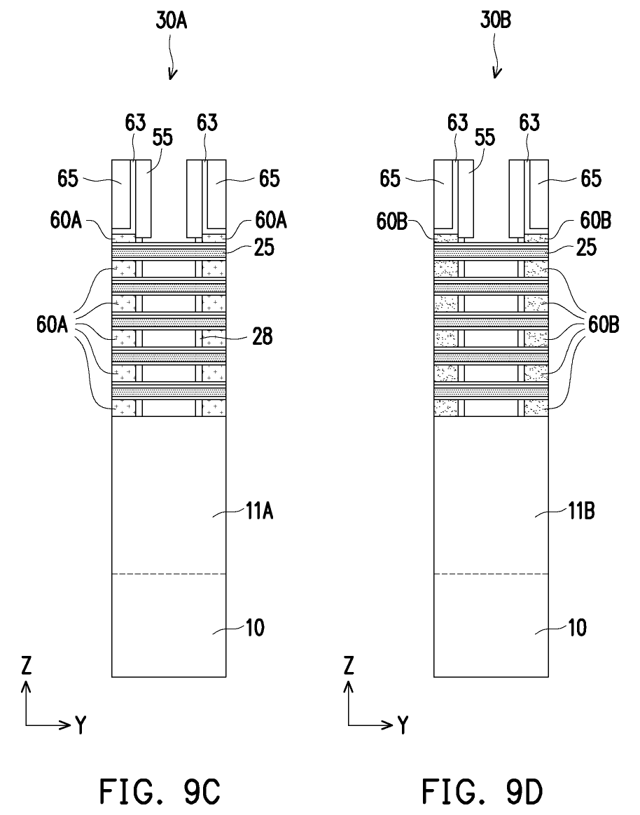

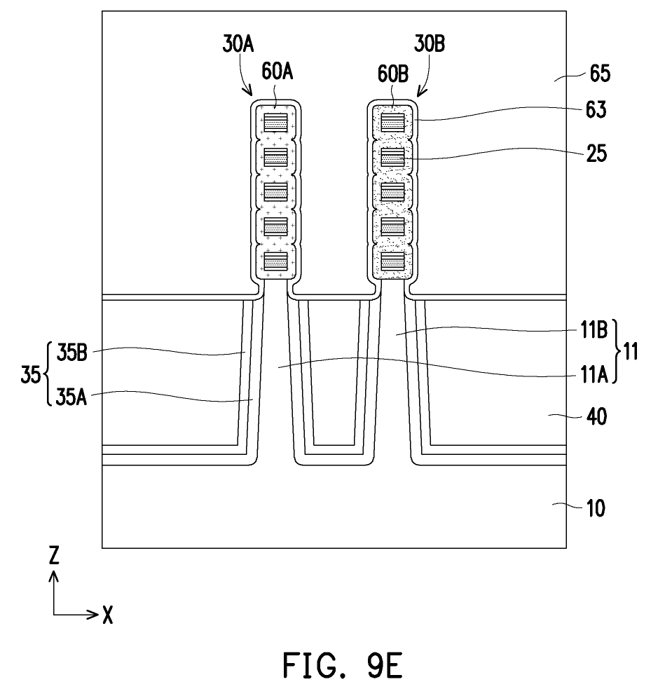

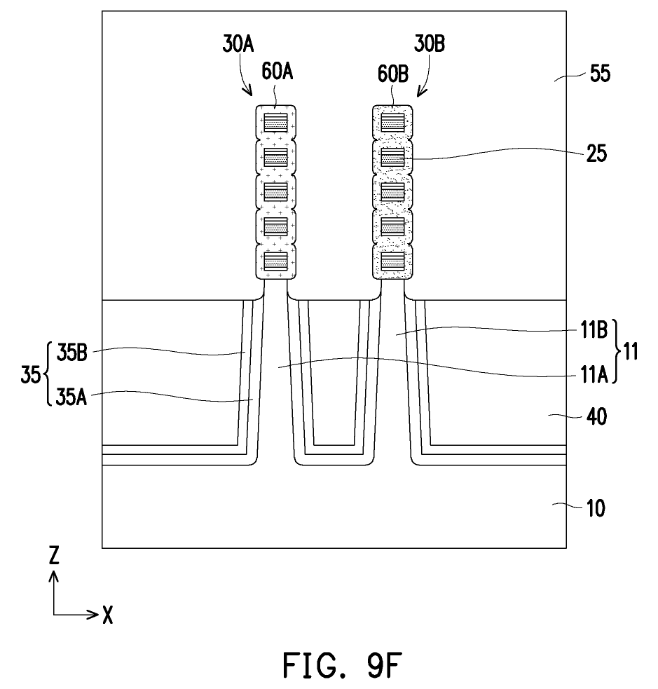

Referring to FIGS. 9A-9F, subsequently, a first insulating liner layer 63 is formed and then an interlayer dielectric (ILD) layer 65 is formed, and then the sacrificial gate structure 50 is removed to form a gate space between the gate sidewall spacers 55. FIG. 9A shows a perspective view, FIG. 9B shows a cross sectional view along the X direction cutting the channel region, FIG. 9C shows a cross sectional view along the Y direction cutting the upper fin structure 30A, FIG. 9D shows a cross sectional view along the Y direction cutting the upper fin structure 30B, FIG. 9E shows a cross sectional view along the X direction cutting the source/drain region, and FIG. 9F shows a cross sectional view along the X direction cutting the gate sidewall spacer 55.

The first insulating liner layer 63 is made of a silicon nitride-based material, such as silicon nitride, and functions as a first contact etch stop layer (CESL) in the subsequent etching processes. The materials for the first ILD layer 65 include compounds including Si, O, C and/or H, such as silicon oxide, SiCOH and SiOC. Organic materials, such as polymers, may be used for the first ILD layer 65. After the first ILD layer 65 is formed, a planarization process, such as CMP, is performed, so that the sacrificial gate electrode layer 54 is exposed.

Next, as illustrated in FIGS. 9A-9F, after the sacrificial gate electrode layer 54 is removed, portions of the dielectric layers 20 as well as portions of the multi-film layers 25 (e.g., nano-sized semiconductor wires) in the gate space are revealed. Specifically, the portions of the dielectric layers 20 which are laterally distributed between the inner spacers 28 are removed. The first ILD layer 65 may protect the first and second S/D epitaxial layers 60A and 60B from damage during the removal of the sacrificial gate structure 54. The sacrificial gate structure 54 may be removed using plasma dry etching and/or wet etching. When the sacrificial gate electrode layer 54 is polysilicon and the first ILD layer 65 is silicon oxide, a wet etchant such as a tetramethylammonium hydroxide (TMAH) solution can be used to selectively remove the sacrificial gate electrode layer 54.

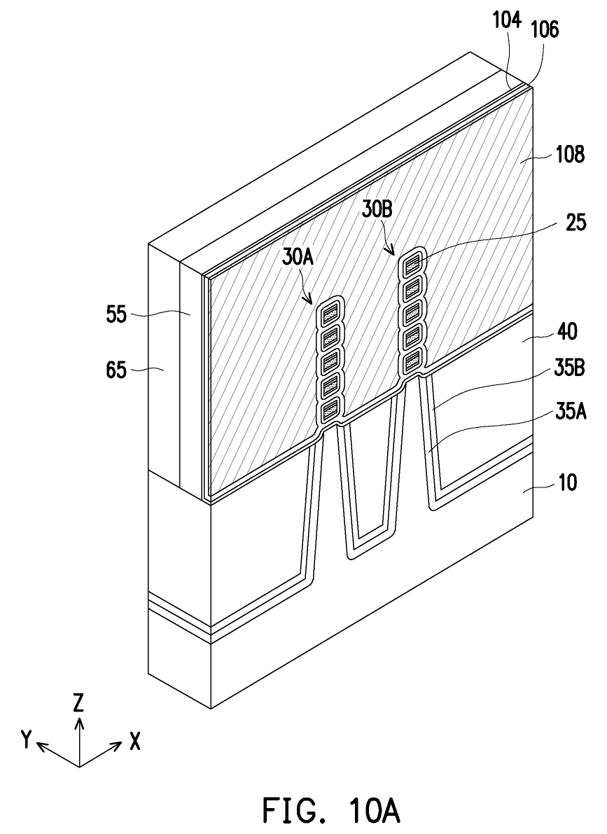

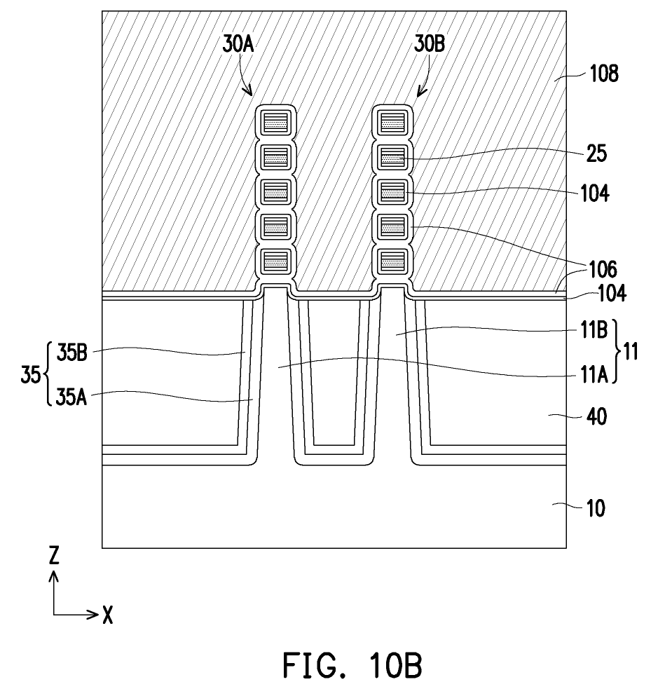

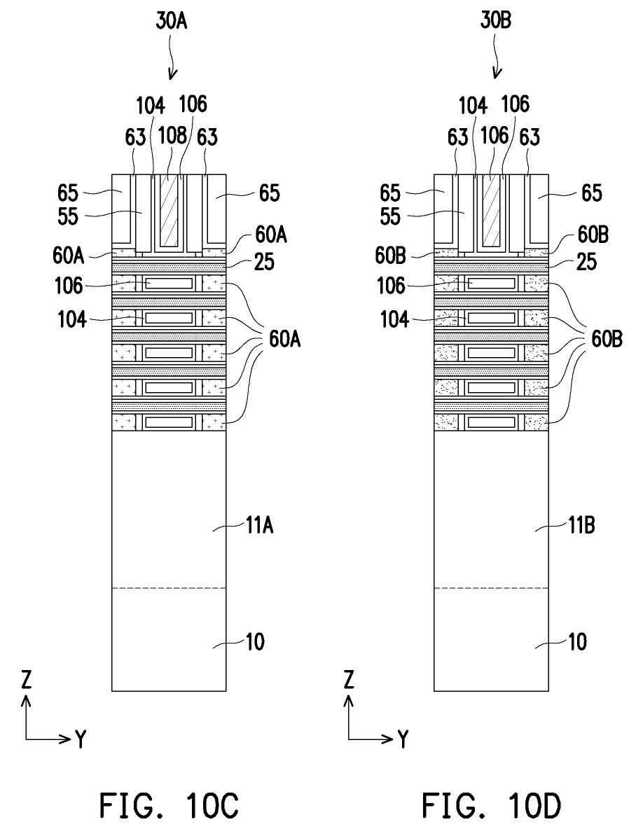

Referring to FIGS. 10A-10D, after the nano-sized semiconductor wires of the multi-film layers 25 are exposed, a gate replacement process is performed. A gate dielectric layer 104 is formed around the nano-sized semiconductor wires of the multi-film layers 25 in the upper fin structure 30A and the upper fin structure 30B. FIG. 10A shows a perspective view, FIG. 10B shows a cross sectional view along the X direction cutting the channel region, FIG. 10C shows a cross sectional view along the Y direction cutting the upper fin structure 30A, and FIG. 10D shows a cross sectional view along the Y direction cutting the upper fin structure 30B.

In some embodiments, the gate dielectric layer 104 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-k dielectric materials, and/or combinations thereof. In some embodiments, an interfacial layer (not shown) is formed between the channel layers and the gate dielectric layer 104. The gate dielectric layer 104 may be formed by CVD, ALD or any suitable method. In one embodiment, the gate dielectric layer 104 is formed using a highly conformal deposition process such as ALD in order to ensure the formation of a gate dielectric layer having a uniform thickness around each channel layer. The thickness of the gate dielectric layer 104 is in a range from about 1 nm to about 6 nm in one embodiment.

Further, a gate electrode layer 108 is formed over the gate dielectric layer 104 as shown in FIGS. 10A-10D. The gate electrode layer 108 is formed over the gate dielectric layer 104 to surround each channel layer in some embodiments. The gate electrode 108 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layer 108 may be formed by CVD, ALD, electro-plating, or other suitable method. The gate electrode layer is also deposited over the upper surface of the first ILD layer 65. The gate dielectric layer and the gate electrode layer formed over the first ILD layer 65 are then planarized by using, for example, CMP, until the first ILD layer 65 is revealed.

In certain embodiments, one or more work function adjustment layers 106 are interposed between the gate dielectric layer 104 and the gate electrode layer 108. The work function adjustment layers 106 are made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TiN, TiC, Co, TiAl, HfTi, TiSi and TaSi is used as the work function adjustment layer. The work function adjustment layer 106 may be formed by ALD, PVD, CVD, e-beam evaporation, or other suitable process. Further, the work function adjustment layer 106 may be formed separately for the n-channel FET and the p-channel FET which may use different metal layers.

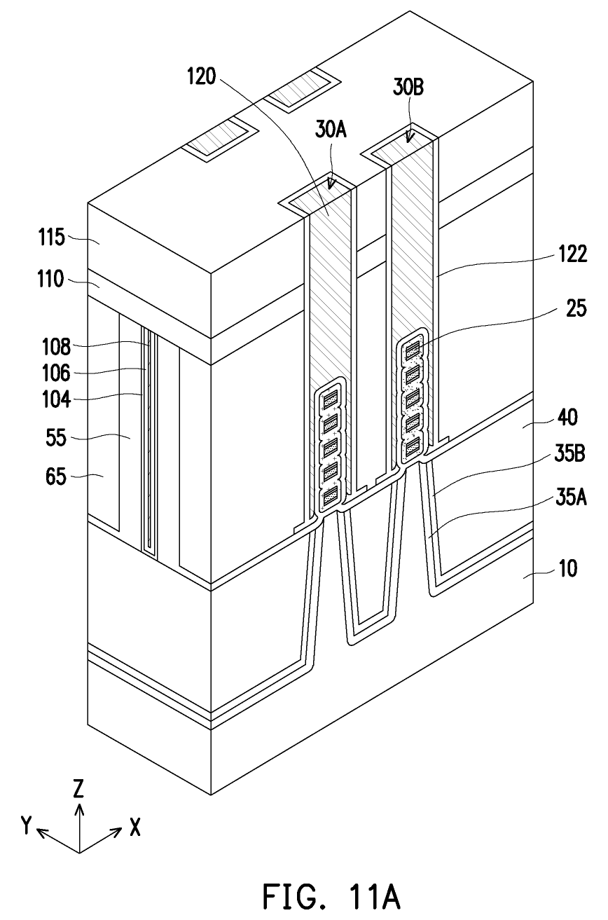

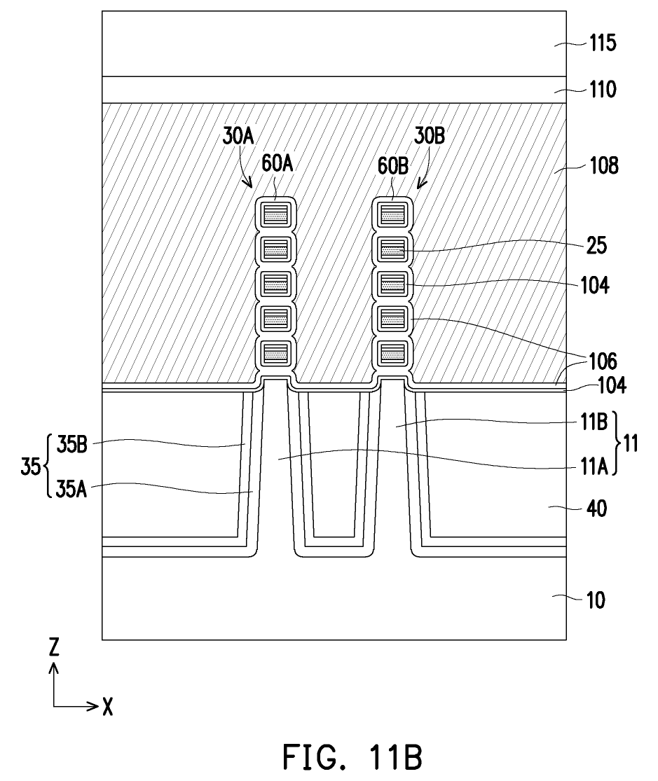

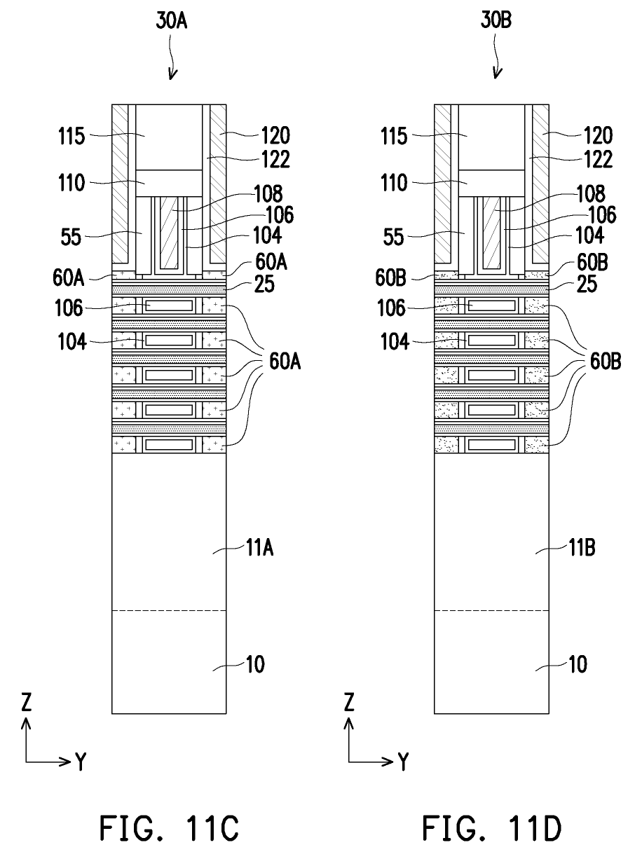

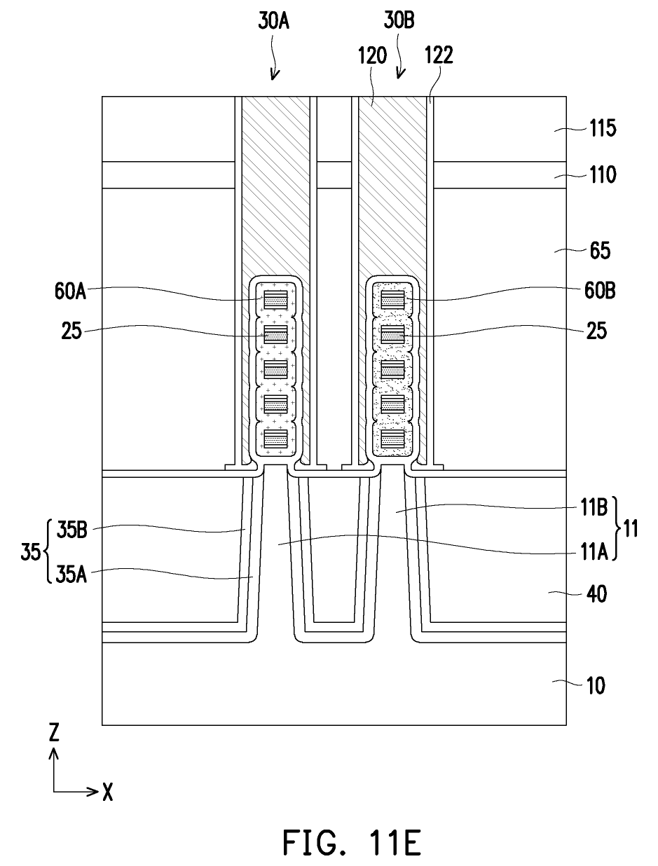

Referring to FIGS. 11A-11E, subsequently, a second insulating liner layer 110 is formed over the first ILD layer 65 and the second ILD layer 115 is formed over the second insulating layer 110. FIG. 11A shows a perspective view, FIG. 11B shows a cross sectional view along the X direction cutting the channel region, FIG. 11C shows a cross sectional view along the Y direction cutting the upper fin structure 30A, FIG. 11D shows a cross sectional view along the Y direction cutting the upper fin structure 30B, and FIG. 11E shows a cross sectional view along the X direction cutting the source/drain region.

The second insulating liner layer 110 is made of a silicon nitride-based material, such as silicon nitride, and functions as a second CESL in the subsequent etching processes. The materials for the second ILD layer 115 include compounds comprising Si, O, C and/or H, such as silicon oxide, SiCOH and SiOC. Organic dielectric materials, such as polymers, may be used for the second ILD layer 110. After the second ILD layer 110 is formed, a planarization process, such as CMP, may be performed.

Then, contact openings are formed to expose the source/drain epitaxial layers 60A and 60B, respectively. The contact openings are filled with one or more layers of conductive materials, thereby forming S/D contacts, as shown in FIGS. 11A-11E. One or more layers of conductive materials are formed in and over the contact openings and then a planarization process, such as a CMP process, is performed to form the S/D contacts with planar top surfaces. In some embodiments, the S/D contact includes a liner layer 122 and a S/D conductor 120. The liner layer 122 is a barrier layer and/or a glue (adhesion) layer. In some embodiments, a Ti layer is formed on the source/drain epitaxial layers 60A and 60B, and a TiN or TaN layer is formed on the Ti layer, wherein the Ti layer and the TiN layer are collectively referred as the liner layer 122. The S/D conductor 120 may include one or more layers of Co, Ni, W, Ti, Ta, Cu and Al, or any other suitable material. As shown in FIGS. 11A-11E, the S/D contact wraps around the source/drain epitaxial layers 60A and 60B.

It is understood that the GAA FETs may undergo further CMOS processes to form various features such as metallic contacts/vias, interconnect metallic layers, interconnect dielectric layers, passivation layers, etc.

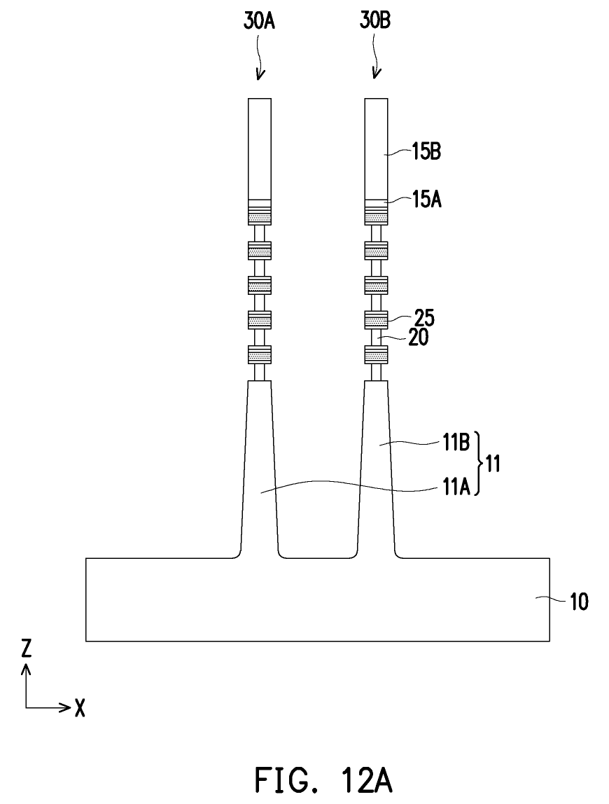

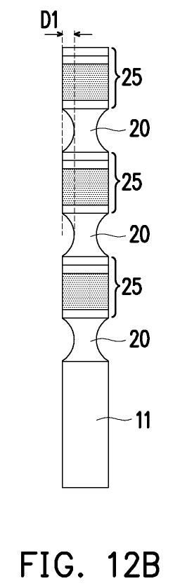

FIGS. 12A and 12B show various views of one of the various stages of a sequential manufacturing process for a GAA FET device according to an alternative embodiment of the present disclosure.

After forming the fin structures 30 (as illustrated in FIGS. 3A and 3B) as well as before forming the fin liner layers 35 and the isolation insulating layer 40 (as illustrated in FIG. 4), a removal process of the dielectric layers 20 may be performed, as illustrated in FIGS. 12A and 12B. After performing the above-mentioned removal process of the dielectric layers 20, the dielectric layers 20 are laterally etched as well as partially etched such that undercut profiles are generated at end surfaces or sidewalls of the dielectric layers 20, as shown in FIGS. 12A and 12B. In some embodiments, a plasma dry etching is used to selectively etch the dielectric layers 20 against the multi-film layers 25, followed by a wet cleaning process using buffered HF. For example, a plasma source gas used in the above-mentioned plasma dry etching includes O₂. In some other embodiments, a wet etching process is used to selectively etch the dielectric layers 20. The etching solution (etchant) may include an aqueous solution of NH₄OH, H₂O₂ and H₂O and/or an aqueous solution of H₂SO₄, H₂O₂ and H₂O. In other embodiments, the wet etchant includes a tetramethylammonium hydroxide (TMAH) solution. In some embodiments, an additional wet cleaning process using buffered HF is performed. In some alternative embodiments, both the plasma dry etching and the wet etching are used. In some embodiments, the etching amount D1 is in a range from about 1 nm to about 10 nm, and is in a range from about 2 nm to about 5 nm. As shown in FIG. 12B, the cross sectional profile of the etched dielectric layers 20 and the multi-film layers 25 includes a dog-bone shape or a thread-spool shape or bobbin shape.

The above-mentioned removal process of the dielectric layers 20 may be performed at various time points. For example, the above-mentioned removal process of the dielectric layers 20 is performed after forming the isolation insulating layer 40 (as illustrated in FIG. 4) as well as before forming the sacrificial gate structure 50 (as illustrated in FIGS. 5A-5D).

The above-mentioned removal process of the dielectric layers 20 (as shown in FIGS. 12A and 12B) may be omitted, and the recessing process (e.g., an etch process) for forming isolation insulating layer 40 (as illustrated in FIG. 4) may laterally and partially etches the dielectric layers 20 such that undercut profiles are generated at end surfaces or sidewalls of the dielectric layers 20.

In some embodiments, the undercut profiles of the end surfaces or sidewalls of the dielectric layers 20 are resulted from the above-mentioned removal process of the dielectric layers 20 (as illustrated in FIGS. 12A and 12B) and the recessing process (e.g., an etch process) for forming isolation insulating layer 40 (as illustrated in FIG. 4).

In some other embodiments, the above-mentioned removal process of the dielectric layers 20 (as shown in FIGS. 12A and 12B) is omitted, and the undercut profiles of the end surfaces or sidewalls of the dielectric layers 20 are resulted from the recessing process (e.g., an etch process) for forming isolation insulating layer 40 (as illustrated in FIG. 4).

In yet other embodiments, the undercut profiles of the end surfaces or sidewalls of the dielectric layers 20 are resulted from the recessing process (e.g., an etch process) for forming isolation insulating layer 40 (as illustrated in FIG. 4) as well as an removal process of the dielectric layers 20, which is performed after forming the isolation insulating layer 40 (as illustrated in FIG. 4) as well as before forming the sacrificial gate structure 50 (as illustrated in FIGS. 5A-5D).

In some alternative embodiments, the undercut profiles of the end surfaces or sidewalls of the dielectric layers 20 are resulted from the recessing process (e.g., an etch process) for forming isolation insulating layer 40 (as illustrated in FIG. 4), a first removal process of the dielectric layers 20 as illustrated in FIGS. 12A and 12B as well as a second removal process of the dielectric layers 20, which is performed after forming the isolation insulating layer 40 (as illustrated in FIG. 4) as well as before forming the sacrificial gate structure 50 (as illustrated in FIGS. 5A-5D).

In another embodiment, the undercut profiles of the end surfaces or sidewalls of the dielectric layers 20 are resulted from a first removal process of the dielectric layers 20 as illustrated in FIGS. 12A and 12B as well as a second removal process of the dielectric layers 20, which is performed after forming the isolation insulating layer 40 (as illustrated in FIG. 4) as well as before forming the sacrificial gate structure 50 (as illustrated in FIGS. 5A-5D).

It will be understood that not all advantages have been necessarily discussed herein, no particular advantage is required for all embodiments or examples, and other embodiments or examples may offer different advantages.

In accordance with one aspect of the present disclosure, a method of manufacturing a semiconductor device is provided. A fin structure including a lower fin structure and an upper fin structure disposed over the lower fin structure is formed, wherein the upper fin structure includes dielectric layers and semiconductor layers alternately stacked, each of the semiconductor layers includes a channel layer, a first protection layer and a second protection layer, and the channel layer is between the first protection layer and the second protection layer. A sacrificial gate structure is formed over the upper fin structure. A source/drain epitaxial layer is formed over a source/drain region of the fin structure after forming the sacrificial gate structure over the upper fin structure. The sacrificial gate structure is removed after forming the source/drain epitaxial layer. The dielectric layers are removed after removing the sacrificial gate structure. A gate structure is formed around the semiconductor layers. In some embodiments, the method further includes: forming an isolation insulating layer around the lower fin structure after forming the fin structure. In some embodiments, forming the fin structure includes: forming stacked layers over a substrate; and patterning the stacked layers and the substrate to form the fin structure comprising the lower fin structure and the upper fin structure. In some embodiments, sidewalls of the channel layer are revealed after removing the sacrificial gate structure. In some embodiments, a bottom surface of the channel layer is covered by the first protection layer, and a top surface of the channel layer is covered by the second protection layer after removing the dielectric layers. In some embodiments, the forming the gate structure includes: forming a gate dielectric layer around the semiconductor layers; and forming a gate electrode layer over the gate dielectric layer. In some embodiments, the method further includes: forming a pair of gate sidewall spacers on opposite sidewalls of the sacrificial gate structure. In some embodiments, the source/drain epitaxial layer is formed over the source/drain region of the fin structure after forming the pair of gate sidewall spacers, and forming the source/drain epitaxial layer includes: partially removing the dielectric layers to reduce lengths of the dielectric layers such that first ends of the dielectric layers are located under the pair of gate sidewall spacers; forming inner spacers on the first ends of the dielectric layers, wherein second ends of the semiconductor layers laterally protrude from the inner spacers after forming the inner spacers on the first ends of the dielectric layers; and forming the source/drain epitaxial layer to cover the inner spacers and the second ends of the semiconductor layers. In some embodiments, the first protection layer includes a first etch resistive layer. In some embodiments, the second protection layer includes an adhesion layer and a second etch resistive layer, wherein the adhesion layer is between the second etch resist layer and the channel layer. In some embodiments, the method of further includes: partially removing the dielectric layers to reduce widths of the dielectric layers before the sacrificial gate structure is formed over the upper fin structure.

In accordance with another aspect of the present disclosure, a method of manufacturing a semiconductor device is provided. A fin structure including sacrificial layers and semiconductor layers alternately stacked is formed, wherein each of the semiconductor layers includes a channel layer, a first protection layer and a second protection layer, and the channel layer is between the first protection layer and the second protection layer. A first gate structure is formed over the fin structure. Gate sidewall spacers are formed on opposite sidewalls of the sacrificial gate structure. A source/drain epitaxial layer is formed at opposite sides of the first gate structure and the gate sidewall spacers. The first gate structure is removed after forming the source/drain epitaxial layer. The sacrificial layers are removed after removing the first gate structure. A second gate structure is formed around the semiconductor layers. In some embodiments, forming the source/drain epitaxial layer includes: partially removing the sacrificial layers to reduce lengths of the sacrificial layers such that first ends of the sacrificial layers are located under the gate sidewall spacers; forming inner spacers on the first ends of the sacrificial layers, wherein second ends of the semiconductor layers laterally protrude from the inner spacers after forming the inner spacers on the first ends of the sacrificial layers; and forming the source/drain epitaxial layer to cover the inner spacers and the second ends of the semiconductor layers. In some embodiments, the inner spacers are in contact with the first protection layer and the second protection layer. In some embodiments, the source/drain epitaxial layer is spaced apart from the first gate structure by the inner spacers before removing the first gate structure.

In accordance with one aspect of the present disclosure, a semiconductor device including multi-layered wires, a gate structure, gate sidewall spacers and a source/drain electrode is provided. The multi-layered wires are disposed over a substrate, wherein each of the multi-layered wires comprises a 2D channel layer, a first protection layer and a second protection layer, and the 2D channel layer is between the first protection layer and the second protection layer. The gate structure is disposed over 2D channel regions of the multi-layered wires. The gate sidewall spacers are disposed on opposite sidewalls of the gate structure. The source/drain electrode is disposed on opposite sides of the gate structure and the gate sidewall spacers. In some embodiments, the semiconductor device further includes inner spacers, wherein the source/drain electrode is laterally spaced apart from the gate structure by the inner spacers. In some embodiments, ends of the multi-layered wires laterally protrude from the inner spacers, and the ends of the multi-layered wires are wrapped around by the source/drain electrode. In some embodiments, the gate structure includes: a gate dielectric layer around the semiconductor layers; and a gate electrode layer disposed over the gate dielectric layer, wherein the gate dielectric layer is in contact with the first protection layer, the second protection layer and sidewalls of the 2D channel layer. In some embodiments, sidewalls of the 2D channel layer are offset from sidewalls of the first protection layer and sidewalls of the second protection layer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
multi-layered wires disposed over a substrate, wherein at least one of the multi-layered wires comprises a 2D channel layer, a first protection layer and a second protection layer, and the 2D channel layer is between the first protection layer and the second protection layer;
a gate structure disposed over channel regions of the multi-layered wires;
gate sidewall spacers disposed on opposite sidewalls of the gate structure; and
a source/drain electrode disposed on opposite sides of the gate structure and the gate sidewall spacers.

2. The semiconductor device of claim 1 further comprising:
inner spacers, wherein the source/drain electrode is laterally spaced apart from the gate structure by the inner spacers.

3. The semiconductor device of claim 2, wherein ends of the multi-layered wires laterally protrude from the inner spacers, and the ends of the multi-layered wires are wrapped around by the source/drain electrode.

4. The semiconductor device of claim 1, wherein the gate structure comprises:
a gate dielectric layer around the multi-film layers; and
a gate electrode layer disposed over the gate dielectric layer, wherein the gate dielectric layer is in contact with the first protection layer, the second protection layer and sidewalls of the channel layer.

5. The semiconductor device of claim 1, wherein sidewalls of the channel layer are offset from sidewalls of the first protection layer and sidewalls of the second protection layer.

6. A semiconductor device, comprising:
a nano-sized semiconductor wire;
a first protection layer covering a top surface of the nano-sized semiconductor wire;
a second protection layer covering a bottom surface of the nano-sized semiconductor wire;
a gate structure wrapping around a channel region of the nano-sized semiconductor wire;
gate sidewall spacers disposed on opposite sidewalls of the gate structure; and
source/drain epitaxial layers disposed on opposite sides of the gate structure and the gate sidewall spacers.

7. The semiconductor device of claim 6, wherein the first protection layer comprises a multi-layered structure, and the second protection layer comprises a single-layered structure.

8. The semiconductor device of claim 6, wherein the first protection layer comprises a first etch resistive layer and an adhesion layer between the first etch resistive layer and the nano-sized semiconductor wire.

9. The semiconductor device of claim 8, wherein a metal ratio in the adhesion layer is greater than a metal ratio in the first etch resistive layer.

10. The semiconductor device of claim 8, wherein the first protection layer comprises a second etch resistive layer.

11. The semiconductor device of claim 10, wherein the first etch resistive layer and the second etch resistive layer are substantially identical in material.

12. The semiconductor device of claim 10, wherein the first etch resistive layer and the second etch resistive layer are substantially identical in material.

13. The semiconductor device of claim 10, wherein a film density of the first etch resistive layer and the second etch resistive layer is greater than a film density of the adhesion layer.

14. The semiconductor device of claim 10, wherein the second etch resistive layer is in contact with the bottom surface of the nano-sized semiconductor wire.

15. The semiconductor device of claim 6, wherein sidewalls of the nano-sized semiconductor wire laterally offset from sidewalls of the first protection layer and sidewalls of the second protection layer.

16. A semiconductor device, comprising:
a nano-sheet;
a first protection layer;
a second protection layer, wherein the first protection layer is spaced apart from the second protection layer by the nano-sheet;
a gate structure wrapping around a channel region of the nano-sheet; and
source/drain epitaxial layers disposed on opposite sides of the gate structure and wrapping around opposite ends of the nano-sheet.

17. The semiconductor device of claim 16, wherein the nano-sheet, the first protection layer and the second protection layer extend through the gate structure laterally.

18. The semiconductor device of claim 16, wherein a top surface of the nano-sheet is covered by the first protection layer, a bottom surface of the nano-sheet is covered by the second protection layer.

19. The semiconductor device of claim 18, wherein the gate structure is spaced apart from the top surface of the nano-sheet by the first protection layer, and the gate structure is spaced apart from the bottom surface of the nano-sheet by the second protection layer.

20. The semiconductor device of claim 16, wherein the gate structure is in contact with sidewalls of the nano-sheet.
